(19) United States
(12) Patent Application Publication
(10) Pub. No.: US 2026/0226620 A1
(43) Pub. Date: Aug. 6, 2026

(54) SUBSTRATE PROCESSING APPARATUS

(71) Applicant: Picosun Oy, Espoo (FI)

(72) Inventors: Niklas HOLM, Espoo (FI); Tom BLOMBERG, Espoo (FI); Kenneth TÖRNROOS, Espoo (FI); Antti KUITUNEN, Espoo (FI); Sami NIVALA, Espoo (FI); Timo VÄHÄ-OJALA, Espoo (FI)

(21) Appl. No.: 19/348,836

(22) Filed: Oct. 3, 2025

(30) Foreign Application Priority Data
Feb. 4, 2025 (FI) 20255087

(51) Int. Cl. C23C 16/455; C23C 16/44

(52) U.S. Cl. CPC C23C 16/45546; C23C 16/4412

(57) ABSTRACT

It is provided a substrate processing apparatus comprising a reaction chamber (110) defining a processing volume (115) for processing a stack of substrates (120), wherein the reaction chamber (110) comprises a downwards tapering bottom (130), wherein the bottom (130) is arranged to taper towards an exhaust outlet (150), and a heating system outside the processing volume (115), wherein the heating system comprises inclined heating elements (320), wherein the inclined heating elements (320) are inclined from vertical so that lower ends of the inclined heating elements (320) are arranged inwards towards the exhaust outlet (150) to heat the tapering reaction chamber bottom (130).

### TECHNICAL FIELD

The present disclosure generally relates to substrate processing. The disclosure relates particularly, though not exclusively, to temperature control of substrate processing apparatuses, such as a substrate processing apparatus comprising a heating system.

### BACKGROUND

This section illustrates useful background information without admission of any technique described herein representative of the state of the art.

In substrate processing, such as atomic layer deposition (ALD), uniform processing conditions are required to produce high-quality uniform coatings. Temperature is one of the important conditions to be controlled. For example, in hot wall ALD reactors, the walls of the processing chamber can be heated to the same temperature as the substrates to be processed.

Processing quality may suffer from poor temperature control. For instance, suboptimal reaction temperatures, temperature differences within and between substrates, or cold spots within the processing chamber or on the substrates tend to result in reduced processing uniformity, for example, due to reduced reaction efficacy or undesired reaction chamber contamination. Therefore, solutions are desired to minimize undesired temperature gradients and cold spots and to provide more accurate and homogeneous temperature control of the processing chamber.

### SUMMARY

It is an object of the present invention to provide a substrate processing apparatus with improved temperature control, or at least provide an alternative to existing solutions. Especially, it is an aim to provide a substrate processing apparatus for processing a batch of substrates with improved temperature control.

The appended claims define the scope of protection. Any examples and technical descriptions of apparatuses, products and/or methods in the description and/or drawings not covered by the claims are presented not as embodiments of the invention but as background art or examples useful for understanding the invention.

According to a first example aspect there is provided a substrate processing apparatus comprising:
a reaction chamber defining a processing volume for processing a stack of substrates, wherein the reaction chamber comprises a downwards tapering bottom, wherein the bottom is arranged to taper (narrow down) towards an exhaust outlet; and
a heating system outside (around) the processing volume, wherein the heating system comprises inclined heating elements, wherein the inclined heating elements are inclined from vertical so that lower ends of the inclined heating elements are arranged inwards towards the exhaust outlet to heat the tapering reaction chamber bottom.

Advantageously, temperature non-uniformity of the reaction chamber may be reduced as heating of the reaction chamber and reaction chamber bottom may be improved. Cold spots close to the exhaust outlet may also be avoided. Accordingly, reaction conditions and processing quality may be improved.

In certain embodiments, the tapering of the bottom comprises narrowing down horizontal cross section of the reaction chamber only along one horizontal dimension, a first horizontal dimension, when approaching the exhaust outlet. Advantageously, improved flow guidance may be enabled while the stack of substrates may be positioned closer to the reaction chamber bottom for processing. Thus, empty space within the reaction chamber may be reduced and processing efficiency improved.

In certain embodiments, the inclined heating elements are arranged symmetrically at opposite sides of the processing volume. In certain embodiments, the inclined heating elements are arranged to follow the tapering of the reaction chamber bottom. Advantageously, uniformity of heating may be improved.

In certain embodiments, the heating system further comprises vertical heating elements arranged outside the processing volume parallel to vertical side walls of the reaction chamber. Advantageously, the heating system comprising differently oriented heating elements may better conform to the shape of the reaction chamber. Further, heating uniformity and efficacy may be improved.

In certain embodiments, the heating system comprises lateral heating elements configured to connect adjacent inclined heating elements and/or vertical heating elements to each other. Advantageously, size and heating efficacy and targeting of the heating may be improved.

In certain embodiments, the heating system is arranged around the processing volume. In certain embodiments, the inclined heating elements, vertical heating elements and lateral heating elements of the heating system are connected to each other to form a continuous heating element around the processing volume. Advantageously, the control and connections of the heating system may be simplified as there is only one continuous heating element.

In certain embodiments, the inclined heating elements comprise at least one bent section to at least partially define the inclination angle of the inclined heating elements. In certain embodiments, the bent section is configured to bring the lower end of the inclined heating element further towards the underside of the narrowing bottom. In certain embodiments, the bent section comprises a kink or a curve. Advantageously, distance of inclined heating elements, placed outside the reaction chamber, from the bottom of the reaction chamber may be more accurately controlled. Further, temperature control of the bottom of the reaction chamber may be further improved.

In certain embodiments, the substrate processing apparatus comprises an outer chamber at least partially surrounding the reaction chamber, wherein the heating elements of the heating system are located outside the reaction chamber within the outer chamber. Advantageously, the heating system may be protected from external disturbances and more accurately controlled. Further, temperature control of the reaction chamber may be improved.

In certain embodiments, the heating elements of the heating system are embedded within walls of the reaction chamber In certain embodiments, the heating elements of the heating system are embedded within the side walls and bottom of the reaction chamber. Advantageously, faster and more effective heating of the reaction chamber may be enabled. Heat energy direction may also be better controlled.

In certain embodiments, the substrate processing apparatus is configured to accommodate the stack of substrates within the processing volume as a horizontal stack of vertically aligned substrates. In certain embodiments, the height direction of the stack is arranged parallel to a second horizontal dimensions, the second horizontal dimension being parallel to the first horizontal direction. Advantageously, the substrate stack may be accommodated close to the tapering reaction chamber bottom. Accordingly, empty space within the processing volume may be minimized. Further, temperature control of the substrates may be improved.

In certain embodiments, the inclined heating elements are transversely located in relation to the height direction of the stack of substrates on opposite sides of the (horizontally aligned) stack. Advantageously, uniformity of heating of the substrate stack may be improved, particularly the heating of the substrates located in the middle of the stack.

In certain embodiments, each end of the horizontal stack of substrates is aligned (perpendicularly) towards one or more vertical heating elements. In certain embodiments, the heating system surrounds the horizontal stack of substrates on a plane defined by the height direction axis of the horizontal stack of substrates. Advantageously, heating of the ends of the substrate stack may be improved. Further, temperature non-uniformity within the substrate stack may be reduced.

In certain embodiments, the (reaction chamber) bottom is configured to conform to the shape (curvature) of the horizontal stack of substrates. Advantageously, substrates within the reaction chamber may be located closer to the reaction chamber bottom. Consequently, processing flow conditions and gas usage may be improved. Furthermore, heating of the substrates by the heating system outside the processing volume may be improved.

In certain embodiments, the reaction chamber has rectangular horizontal cross section. Advantageously a batch of substrates having a rectangular horizontal cross section, such as a horizontally aligned stack of substrates may be snugly accommodated within the reaction chamber. Thus, empty space within the reaction chamber may be minimized and gas usage optimized. Furthermore, heating of the substrates may be improved as the distance between substrates and reaction chamber walls and heaters outside the walls may be minimized.

In certain embodiments, the substrate processing apparatus comprises heating collar arranged to heat the exhaust outlet. Advantageously, temperature control of exhaust outlet and reaction chamber may be further improved and temperature non-uniformity reduced. In certain embodiments, height of the heating system is at least 90% of height of the reaction chamber. Advantageously, temperature of the reaction chamber may be accurately and uniformly controlled over the height of the reaction chamber.

According to a second example aspect, there is provided a reaction chamber comprising heating elements embedded within walls of the reaction chamber. In certain embodiments, the heating elements are configured to follow the shape of the walls of the processing volume. In certain embodiments, the heating elements are configured to control the temperature of the processing volume within the reaction chamber.

Different non-binding example aspects and embodiments have been illustrated in the foregoing. The embodiments in the foregoing are used merely to explain selected aspects or steps that may be utilized in different implementations. Some embodiments may be presented only with reference to certain example aspects. It should be appreciated that corresponding embodiments may apply to other example aspects as well.

### BRIEF DESCRIPTION OF THE FIGURES

Some example embodiments will be described with reference to the accompanying figures, in which:

FIG. 1 schematically shows a cross-sectional side view of a substrate processing apparatus according to certain embodiments;

FIG. 2 schematically shows a cross-sectional side view of another substrate processing apparatus according to certain embodiments;

FIG. 3 schematically shows yet another substrate processing apparatus according to certain embodiments;

FIG. 4 schematically shows a heating collar according to certain embodiments;

FIG. 5 schematically shows an exemplary cutaway drawing of vertical heating elements arranged within a reaction chamber side wall according to certain embodiments; and

FIG. 6 schematically shows a cross-sectional side view of yet another substrate processing apparatus according to certain embodiments.

### DETAILED DESCRIPTION

In the following description, like reference signs denote like elements or steps.

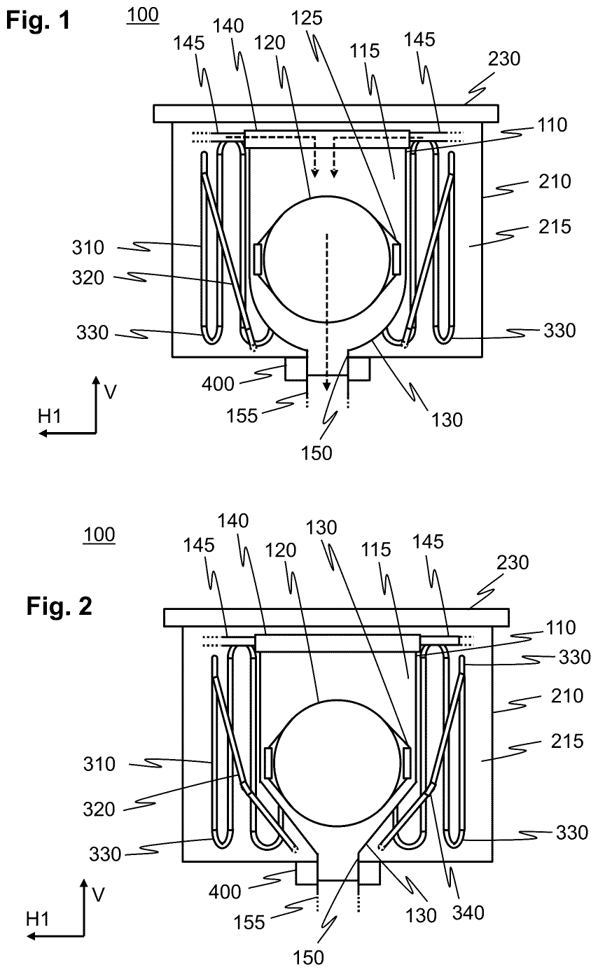

In certain embodiments, described herein is provided a substrate processing apparatus 100 comprising a heating system. Exemplary substrate processing apparatuses 100 are shown in FIGS. 1-3 and 6.

In certain embodiments, the substrate processing apparatus 100 comprises a reaction chamber 110 defining a processing volume 115 for processing a batch of substrates 120. In certain embodiments, the reaction chamber 110 comprises a downwards tapering bottom 130. In certain embodiments, the bottom 130 is arranged to taper (downwards) towards an exhaust outlet 150. In certain embodiments, the substrate processing apparatus 100 comprises a heating system outside the processing volume 115. In certain embodiments, the heating system comprises inclined heating elements 320. In certain embodiments, the inclined heating elements 320 are arranged outside the processing volume 115. In certain embodiments, the inclined heating elements 320 are inclined (away) from vertical, so that lower ends of the inclined heating elements 320 are arranged inwards towards the exhaust outlet 150 to heat the tapering reaction chamber bottom 130. Advantageously, temperature control of the reaction chamber 110, particularly the bottom 130 and exhaust outlet 150, may be improved as the inclined heating elements are located closer to the bottom 130 and are arranged to follow the shape of the reaction chamber 110 and the tapering bottom 130. Consequently, temperature uniformity within the reaction chamber 110 may be improved. Also, undesired cold spots at the bottom of the reaction chamber 100 may be reduced as the underside of the bottom 130 may be effectively heated.

In certain embodiments, the heating system is configured to regulate the temperature of the reaction chamber 110 and the processing volume 115 therein. In certain embodiments, the heating system is configured to maintain the reaction chamber 110 and the substrates 120 within the reaction chamber 110 at a homogeneous temperature. In certain embodiments, the heating system comprises resistive heating elements. Advantageously, stable processing conditions may be achieved. Consequently, processing quality may be improved. Further, film growth rate may be improved due to more stable conditions throughout the reaction chamber 110.

In certain embodiments, the heating system is arranged around the processing volume.

In certain embodiments, (heating elements of) the heating system is arranged around the reaction chamber 110. In certain embodiments, the heating system is arranged outside the reaction chamber 110 adjacent to side walls 160 of the reaction chamber 110. In certain embodiments, the heating elements of the heating system are not in direct (physical) contact with the reaction chamber 110. Accordingly, in certain embodiments, the heating system is configured to heat the reaction chamber by radiation. Advantageously, more uniform heating may be achieved.

In certain embodiments, the substrate processing apparatus 100 comprises a reaction chamber 110 for processing a stack of substrates 120, wherein the reaction chamber 110 comprises a downwards tapering bottom 130, wherein the bottom 130 is arranged to taper towards the exhaust outlet 150, and the heating system outside the reaction chamber 110, wherein the heating system comprises inclined heating elements 320 arranged adjacent to side walls 160 of the reaction chamber 110, wherein the inclined heating elements 320 are inclined from vertical so that lower ends of the inclined heating elements 320 are arranged inwards towards the underside of the tapering reaction chamber bottom 130. A schematic example of such a substrate processing apparatus is shown in FIGS. 1, 2 and 3.

In certain embodiments, heating elements 310, 320, 330 of the heating system are embedded within the reaction chamber side walls and bottom 130. That is, in certain embodiments, the heating system is in direct physical contact with the reaction chamber 110. Advantageously, faster heating may be enabled and heat energy directed more accurately.

In certain embodiments, the substrate processing apparatus 100 comprises a reaction chamber 110 for processing a stack of substrates 120, wherein the apparatus 100 comprises heating elements 310, 320, 330 embedded within walls of the reaction chamber 110 to regulate temperature of the processing volume 115 within the reaction chamber 110. A schematic example of such an apparatus 100 is shown in FIG. 6. Advantageously, the temperature control of the processing volume may be improved and made more homogeneous. In certain embodiments, the shape of the heating elements 310, 320, 330 is configured to follow the shape of the walls of the reaction chamber 110.

Substrate processing apparatuses, or surface deposition apparatuses, in the context of the present disclosure are configured to exploit principles of vapor-deposition based techniques. In preferred embodiments, the substrate processing apparatus is an ALD apparatus. As used herein, the term ALD comprises all applicable ALD based techniques and any equivalent or closely related technologies, such as, for example the following ALD sub-types: MLD (Molecular Layer Deposition), plasma-assisted ALD, such as PEALD (Plasma Enhanced Atomic Layer Deposition) and photon-enhanced Atomic Layer Deposition (known also as flash enhanced ALD).

The skilled person is aware of the principles of ALD. In ALD, at least one substrate is typically exposed to temporally separated precursor pulses in a reaction vessel to deposit material on the substrate surfaces by sequential self-saturating surface reactions. ALD advantageously enables manufacturing of thin films that are uniform, dense and pinhole free.

In certain embodiments, the substrate processing apparatus is applied to other deposition technologies, such as physical vapor deposition (PVD), chemical vapor deposition (CVD) and plasma-enhanced chemical vapor deposition (PECVD).

In certain embodiments, the substrate processing apparatus is an atomic layer etching (ALE) apparatus. In certain embodiments, the substrate processing apparatus 100 comprises a vertical flow reaction chamber 110, wherein reactant flow direction is from top (part) of the reaction chamber 110 (downwards) towards the exhaust outlet 150 located at the bottom 130 of the reaction chamber 110.

As used herein, fluid may refer to liquid or gas. However, in the context of the present disclosure, fluids are preferably gaseous substances, comprising precursor chemical(s), (inert) carrier gas(es) and purging gas(es) used in substrate processing. Fluid may also refer to a mixture of two or more gases.

Structural features of the substrate processing apparatus 100 according to certain embodiments are described below with respect to FIGS. 1-3 and 6. Directional indicators, or coordinate axes, labelled herein as first horizontal dimension H1, second horizontal dimension H2, and vertical dimension V are marked in FIGS. 1-3 and 6 to assist the reader. The first horizontal dimension H1, second horizontal dimension H2, and vertical dimension V are perpendicular to each other. Note that in FIGS. 1, 2 and 6 the second horizontal dimension H2 is perpendicular to the page and, thus, not visible.

In certain embodiments, the substrate processing apparatus 100 is an ALD apparatus. In certain embodiments, the substrate processing apparatus 100 is a CVD apparatus. Advantageously, uniform thin films may be manufactured.

In certain embodiments, the substrate processing apparatus 100 comprises a reaction chamber 110. The reaction chamber 110 defines a processing volume 115 within the reaction chamber 110. One or more substrates 120 may be processed within the processing volume 115. In certain embodiments, the reaction chamber 110 is configured for processing a batch of substrates 120. In certain embodiments, the reaction chamber 110 is configured for processing a stack of substrates 120.

In certain embodiments, the reaction chamber 110 is a vertical flow reaction chamber. In certain embodiments, the flow of reaction chemicals within the vertical flow reaction chamber proceeds vertically from top to bottom. Vertical fluid flow direction within the reaction chamber 110 according to certain embodiments is schematically depicted with dashed arrows in FIG. 1.

In certain embodiments, the substrate processing apparatus 100 is configured to accommodate a batch of substrates 120 within the processing volume 115. The batch of substrates 120 comprises a plurality of substrates 120. In certain embodiments, the batch (stack) of substrates comprises 6-35 substrates 120. In certain embodiments, the batch (stack) of substrates 120 comprises more than 30 substrates 120. In certain embodiments, the substrates 120 are circular wafers.

In certain embodiments, the batch of substrates 120 is arranged as a stack of substrates 120 for processing. In certain embodiments, the substrates 120 in the stack are arranged on top of each other, planar surfaces of the substrates 120 facing each other and spaced apart so that fluid flow through the stack and between adjacent planar surfaces is enabled. In certain embodiments the stack of substrates 120 has a cylindrical shape.

The stack of substrates (120) has a height axis or height direction which is perpendicular to the planar substrate surfaces within the stack. The length of the stack along the height axis defines the height of the stack. In certain embodiments, the height axis of the stack is parallel or corresponds to the longitudinal dimension of the stack. In certain embodiments, the diameter of the substrates 120 within the stack corresponds to the width of the stack.

In certain embodiments, the substrate processing apparatus 100 is configured to accommodate the stack of substrates 120 within the reaction chamber 110 as a horizontal stack of vertically aligned substrates 120. That is, the height direction of the stack of substrates 120 is arranged parallel to a horizontal direction, while the planar surfaces of the substrates 120 are arranged vertically perpendicular to the bottom 130. For example, in FIGS. 1-3 and 6, the height direction of the substrate stack within the reaction chamber 110 is arranged parallel to the second horizontal direction H2. Advantageously, more homogeneous vertical fluid flow through the stack of substrates 120 may be enabled as the individual substrates within the stack are vertically aligned. Consequently, processing quality and uniformity may be improved.

In certain embodiments, the substrate processing apparatus 100 comprises a substrate holder (or a cassette) 125 for holding the stack of substrates 120 within the reaction chamber 110. In certain embodiments, the apparatus 100 comprises a loading arm to transfer the substrate holder 125 to or from the processing volume 115. Advantageously, the stack of substrates 120 may be processed and handled more effectively as one unit.

In certain embodiments, the stack of substrates 120 is loaded to the reaction chamber through top 140 of the reaction chamber. In certain embodiments, the stack of substrates 120 is unloaded from the reaction chamber 110 through the top 140 of the reaction chamber 110.

In certain embodiments, the reaction chamber 100 comprises an exhaust outlet 150. Processing fluids may be removed from the reaction chamber 110 through the exhaust outlet 150. In certain embodiments, the exhaust outlet 150 is located at the bottom 130 of the reaction chamber 110. In certain embodiments, the exhaust outlet 150 is located at the lowest part of the reaction chamber bottom 130. In certain embodiment, the exhaust outlet 150 is located centrally at the bottom 130. Advantageously, more uniform vertical flow within the processing volume 115 may be enabled and promoted.

In certain embodiments, the exhaust outlet 150 is connected to an exhaust line 155. In certain embodiments, the exhaust outlet 150 is connected to an exhaust line 155 outside the reaction chamber 110. In certain embodiments, the exhaust outlet 150 is connected to a vacuum pump via the exhaust line 155. Advantageously, removing processing fluids from the processing volume 115 may be enhanced.

In certain embodiments, the reaction chamber 110 comprises the bottom 130. In certain embodiments, the reaction chamber 110 comprises a top wall 140. The top wall 140 is located opposite to the bottom 130 on an opposite side of the processing volume 115. In certain embodiments, the reaction chamber 110 comprises side walls 160. In certain embodiments, the side walls 160 connect the bottom 130 to the top wall 140. In certain embodiments, the processing volume 115 is defined by (inside of) the bottom 130, top wall 140 and vertical side walls 160.

In certain embodiments, the bottom 130 is configured to form a bottom wall of the reaction chamber 110. In certain embodiments, the bottom 130 is a downwards tapering bottom 130, wherein the bottom 130 is arranged to taper downwards towards an exhaust outlet 150. That is, the horizontal cross-section of the bottom 130 is configured to become narrower, the closer the exhaust outlet 150 the cross section is located. Advantageously, fluid flow within the reaction chamber may be effectively guided towards the exhaust outlet 150. Consequently, homogeneous flow conditions within the reaction chamber 110 may be improved. Further, processing quality may be improved as a result.

In certain embodiments, the tapering of the bottom 130 comprises narrowing down horizontal cross section of the reaction chamber 110 only along one horizontal dimension, a first horizontal dimension H1, when (vertically) approaching the exhaust outlet 130. That is, otherwise the cross-sectional dimension, parallel to the second horizontal dimension H2 which is perpendicular to the first horizontal cross section, of the reaction chamber 110 remains unchanged. In certain embodiments, the bottom 130 is arranged to narrow down, in the first horizontal dimension H1, when vertically approaching the exhaust opening 150 of the reaction chamber 110. Advantageously, as the bottom 130 narrows down only along one horizontal dimension, a horizontal stack of vertically aligned substrates, having its height direction parallel to the second horizontal dimension, may be still positioned close to the bottom of the reaction chamber 110. Consequently, amount of empty space between the stack of substrates 120 and the bottom 130 of the reaction chamber 110 may be minimized. Consequently, use and flow of reaction gases and processing efficacy may be improved. Further, the temperature of the substrates 120 may be better controlled by heating system located outside the reaction chamber 100 when the substrates are located close to the reaction chamber walls.

The bottom 130 of the reaction chamber 110 is not horizontally flat but has three-dimensional shape. Accordingly, the bottom 130 may be tapered, inclined or curved towards the exhaust outlet. Therefore, horizontal cross section of the reaction chamber 110 (when the cross section is at least partially defined by the bottom 130 at the bottom of the reaction chamber 110) becomes narrower at least in one horizontal direction (i.e. width or depth of the reaction chamber 110) when approaching the exhaust outlet 130 in vertical direction. Advantageously, (vertical) fluid flow may be more effectively directed towards the exhaust outlet 150. Accordingly, more uniform fluid flow within the reaction chamber 110 may be achieved.

In certain embodiments, horizontal cross section of the reaction chamber 110, wherein the cross section is at least partially defined by the bottom 130, is arranged to narrow down in at least one horizontal dimension, first horizontal dimension H1, when approaching the exhaust outlet 130 in vertical direction. In certain embodiments, horizontal cross section of the reaction chamber 110, wherein the cross section is at least partially defined by the bottom 130, is arranged to narrow down only in direction parallel to the first horizontal dimension. In certain embodiments, horizontal cross section of the reaction chamber 110, the cross section being at least partially defined by the bottom 130, is arranged to narrow down in first horizontal dimension which is parallel to the side wall of the reaction chamber 110 which is parallel to planar surfaces of substrates 120 arranged within the reaction chamber 110 for processing.

In certain embodiments, the bottom 130 is a curved wall. In certain embodiments, the bottom 130 comprises at least two straight or curved wall sections that are inclined towards the exhaust outlet 150. In certain embodiments, the bottom 130 comprises two inclined straight or inwards curved wall sections that are mirror images of each other. In certain embodiments, the bottom 130 comprises two straight or curved wall sections that are inclined towards the exhaust outlet 150 wherein the exhaust outlet 150 is located between the two inclined wall sections. In certain embodiments, the bottom 130 has a funnel-shaped vertical cross section (when viewed from at least one horizontal direction parallel to at least on vertical side wall). In certain embodiments, the bottom 130 has a semicylindrical shape.

In certain embodiments, the bottom 130 is configured to conform to a shape of the stack of substrates 120 arranged within the reaction chamber 110. In certain embodiments, the bottom 130 is configured to conform to a curvature of a cylindrical stack of substrates 120 arranged within the reaction chamber 110, wherein the stack of substrates 120 is a horizontal stack of vertically arranged substrates 120 (that is, the height direction of the stack 120 is arranged parallel to a horizontal direction and planar surfaces of the substrates 120 are perpendicular to the bottom 130). Advantageously, empty space within the reaction chamber 110 between the bottom 130 and the stack of substrates 120 may be minimized. Further, controlling of the temperature of the substrates 120 by heating elements 310, 320, 330 located outside the reaction chamber 110 may be improved.

In certain embodiments, the top wall 140 of the reaction chamber 110 comprises an openable and closable lid for loading and unloading the stack of substrates 120. In certain embodiments, the top wall 140 is formed by the lid. Accordingly, the stack of substrates 120 may be loaded and unloaded through the top of the reaction chamber 110. In certain embodiments, the lid forming the top wall 140 is sealable. In certain embodiments, a horizontal stack of substrates 120 is loaded or unloaded to or from the reaction chamber 110, respectively, through the top wall 140.

In certain embodiments, the top wall 140 comprises one or more processing fluid inlet 145 for providing processing fluid flow into the reaction chamber 110. Advantageously, vertical fluid flow may be provided from the top 140. The processing fluid may comprise reaction precursors, mixture of reaction precursors and inert carrier gas, plasma or plasma precursors, or purge gas. The one or more fluid inlet 145 is connected to one or more fluid sources located outside the substrate processing apparatus 100 via appropriate fluid lines (the fluid lines or sources are omitted from FIGS. 1-3 and 6).

In certain embodiments, the reaction chamber 110 comprises four side walls 160. In certain embodiments, the reaction chamber 110 comprises vertical side walls 160. In certain embodiments, the reaction chamber 110 comprises four vertical side walls 160. Advantageously, the reaction chamber 110 may have horizontal cross-sectional shape which closely conforms to dimensions of a horizontal stack of vertically aligned substrates 120. Consequently, empty space within the processing volume 115 may be minimized. Further, temperature control of the substrates 120 by heating elements located outside the reaction chamber walls may be improved. Further, processing quality and efficacy may be improved.

In certain embodiments, the reaction chamber 110 has a rectangular horizontal cross section defined by the four vertical side walls 160. In certain embodiments, the reaction chamber 110 is arranged to have a rectangular horizontal cross section configured to conform to a rectangular shape of a horizontal stack of vertically aligned substrates 120 arranged within the reaction chamber 110. In certain embodiments, the reaction chamber 110 has rectangular horizontal cross section configured to accommodate a horizontal stack of vertically aligned substrates 120. Advantageously, empty space around the stack of substrates 120 within the reaction chamber 110 may be minimized. Accordingly, fluid flow through the stack of substrates 120 may be improved and consequently, processing quality improved. Further, more accurate temperature control between the substrates 120 and the reaction chamber walls may be established. Still further, undesired temperature gradients may be minimized. Still further, homogeneous, or even laminar, flow conditions within the reaction chamber may be improved when substrates are aligned parallel to vertical flow.

The substrate processing apparatus 100 comprises a heating system outside the processing volume 115. In certain embodiments, the substrate processing apparatus 100 comprises the heating system around the processing volume 115. The heating system is configured to control the temperature of the reaction chamber 110 and processing volume 115.

In certain embodiments, the substrate processing apparatus 100 comprises the heating system outside the reaction chamber 110 adjacent to reaction chamber side walls 160. Exemplary substrate processing apparatuses 100 comprising such a heating system are schematically depicted in FIGS. 1-3. In certain embodiments, the substrate processing apparatus 100 comprises a heating system arranged around the reaction chamber 110. In certain embodiments the heating system is arranged to extend around the reaction chamber 110 along a horizontal plane. In certain embodiments, the heating system is arranged as a fence surrounding the reaction chamber 110 the comprising inclined heating elements 320 arranged adjacent to side walls 160 of the reaction chamber 110. That is, in certain embodiments, the heating system surrounds the side walls 160 of the reaction chamber 110.

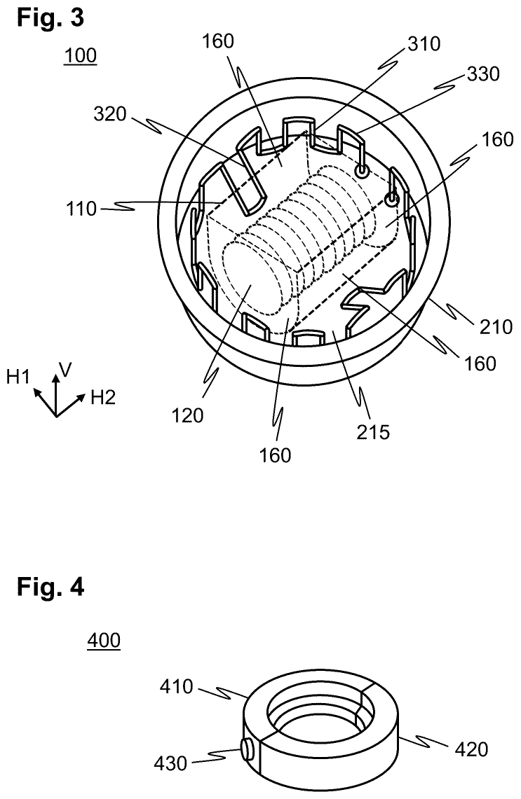

In certain embodiments, the heating system is arranged as a circular fence around the reaction chamber 110 as depicted in FIG. 3. In certain embodiments, the heating system is arranged as rectangular fence around the reaction chamber 110 so that the heating system conforms to the cross-sectional shape of the reaction chamber 110. Advantageously, heating of the side walls 160 may be controlled by the shape and arrangement of the heating system.

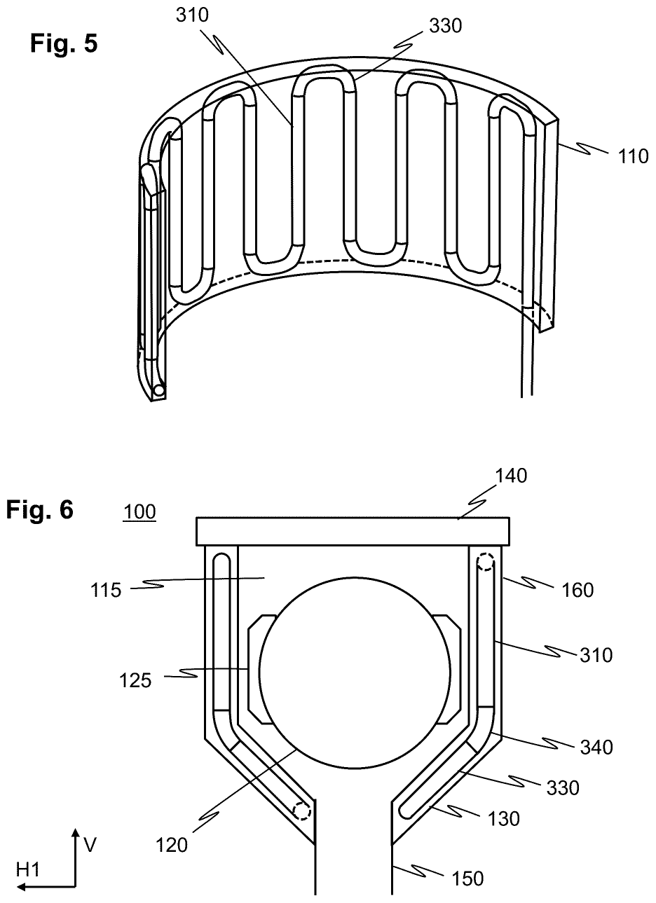

In certain embodiments, the apparatus 100 comprises heating elements embedded within walls of the reaction chamber 110 (i.e. around the processing volume 115). In certain embodiments, the apparatus 100 comprises heating elements of the heating system embedded within the side walls 160 of the reaction chamber 110. In certain embodiments, the apparatus 100 comprises heating elements of the heating system embedded within the bottom 130 of the reaction chamber 110. In certain embodiments, the apparatus 100 comprises heating elements of the heating system embedded within the side walls 160 and the bottom 130 of the reaction chamber 110. That is, in certain embodiments, there is a direct heat-conducting contact between the reaction chamber 110 and the heating elements 310, 320, 330 of the heating system. This way a hot-wall reaction chamber with embedded heating system may be obtained. Advantageously, faster processing volume heating may be enabled. Exemplary arrangement of vertical heating elements 310 arranged within a curved side wall 160 is shown in FIG. 5. FIG. 6 schematically shows a cross-sectional view of an exemplary substrate processing apparatus comprising heating elements embedded within the side walls 160 and the downwards tapering bottom 130.

In certain embodiments, heating elements of different shapes and sizes are embedded within the walls of the reaction chamber 110. Advantageously, reaction chamber walls of different shapes and orientations may be effectively heated.

In certain embodiments, the heating elements embedded within the walls of the reaction chamber 110 are arranged to form a continuous heating element around the processing volume. Advantageously, control of the heating system may be simplified as the heating elements are interconnected.

In certain embodiments, reaction chamber side walls 160 and/or bottom 130 with embedded heating elements 310, 320, 330 are manufactured by hot isostatic pressing (HIP). In certain embodiments, the reaction chamber side walls 160 and/or bottom 130 with embedded heating elements 310, 320, 330 are manufactured by casting. In certain embodiments, the side walls 160 and/or bottom 130 of the reaction chamber 110 are made of metal. Advantageously, the reaction chamber side walls 160 and/or bottom 130 may be manufactured so that zero clearance remains between the heating elements and the bulk material of the side walls 160 and/or bottom 130. Consequently, transfer of heat energy from the heating elements to the reaction chamber may be improved and heating time reduced.

In certain embodiments, the height of the heating system is at least 90% of the height of the reaction chamber 100. In certain embodiments, the height of the inclined heating elements 320 is at least 90%, preferably at least 95%, of the height of the reaction chamber 100. In certain embodiments, the heating system height is defined as a (vertical) height difference from the highest part of (the heating elements of) the heating system to the lowest part of (the heating elements of) the heating system. In certain embodiments, the height of the reaction chamber 110 is defined as the distance from the lowest part of the bottom 130 to the top part of the top wall 140. In certain embodiments, the height of the heating system (measured as the height difference of the highest and lowest part of the heating system) is at least equal to the height of the processing volume 115 (i.e., inside volume of the reaction chamber 110 measured from bottom 130 to top wall 140 within the reaction chamber 110). Advantageously, the reaction chamber 110 may be effectively and uniformly heated over the entire height of the reaction chamber 110

In certain embodiments, the height of the heating system around the reaction chamber 110 is not constant. Advantageously, the heating system may comprise heating elements of different heights and its geometry may be adjusted to take into account and not compromise structural details of the substrate processing apparatus 100, such as important fluid inlet 145 locations.

In certain embodiments, the heating system comprises one or more vertically aligned vertical heating element 310. In certain embodiments, vertical heating elements are arranged adjacent to vertical reaction chamber side walls 160 outside the reaction chamber 110. In certain alternative embodiments, the vertical heating elements 310 are embedded within the reaction chamber side walls 160.

In certain embodiments, a vertical heating element 310 comprises top end and bottom end, wherein the top end and the bottom end of the vertical heating element 310 are located equally far from the vertical central axis of the reaction chamber 110. In certain embodiments, each of the one or more vertical heating element 310 is parallel to the vertical side walls 160 of the reaction chamber 110. In certain embodiments, each of the one or more vertical heating element 310 is parallel to the vertical central axis of the reaction chamber 110. Advantageously, the vertical side walls 160 of the reaction chamber 110 may be effectively and evenly heated by the vertical heating elements 310.

In certain embodiments, the heating system comprises at least two inclined heating elements 320. In certain embodiments, the inclined heating elements 320 are arranged adjacent to vertical reaction chamber side walls 160 outside the reaction chamber 110. In certain alternative embodiments, the inclined heating elements 320 are embedded within bottom 130 of the reaction chamber 110. In certain embodiments, the inclined heating elements 320 are embedded within walls of the reaction chamber 110. In certain embodiments, the apparatus 100 comprises 2-10 inclined heating elements. However, the optimal amount of heating elements depends on the dimensions and size of the reaction chamber 100 to be heated and the shape and size of the heating elements, as well as their heating efficacy.

In certain embodiments, the inclined heating element 320 is a straight member wherein bottom end of the straight member is arranged to deviate from vertical towards the reaction chamber 110. In certain embodiments, the inclined heating elements 320 are inclined away from vertical so that the lower end of the inclined heating elements 320 is arranged inwards towards the underside of the tapering reaction chamber bottom 130. Advantageously, temperature control of the reaction chamber bottom may be improved.

In certain embodiments, the inclined heating elements 320 are arranged at opposite sides of the processing volume 115. In certain embodiments, the inclined heating elements (320) are arranged symmetrically at opposite sides of the processing volume 115. In certain embodiments, the inclined heating elements (320) are arranged adjacent to widest side walls 160 of the reaction chamber 110. Advantageously, more uniform heating of the reaction chamber 110 may be provided.

In certain embodiments, the substrate processing apparatus 100 comprises inclined heating elements 320 located at least at the sides of the reaction chamber 110, wherein the bottom 130 narrows down towards the exhaust outlet 150. Exemplary positioning of such inclined heating elements 320 is clearly depicted in perspective view of FIG. 3, wherein the reaction chamber 110 and stack of substrates 120 within the reaction chamber 110 are marked with dashed outlines within an outer chamber 210 and surrounded by the heating system.

In certain embodiments, the inclined heating elements 320 are transversely located in relation to the height axis of the stack of substrates (120), wherein the stack is accommodated within the reaction chamber as a horizontal stack of vertically aligned substrates 120. In certain embodiments, the inclined heating elements 320 are transversely located in relation to the height axis of the stack of substrates (120) at opposite sides of the stack.

In certain embodiments, each of the inclined heating elements 320 comprises a top end and a bottom end, wherein the bottom end is arranged inwards towards the bottom 130 so that the bottom end is closer to the vertical central axis of the reaction chamber 110 than the top end. In certain embodiments, the bottom end of each of the inclined heating elements 320 is arranged towards the bottom 130. In certain embodiments, the inclined heating elements 320 are arranged to (at least partially) follow the angle, tangent or curvature of the bottom 130. In certain embodiments, the inclined heating elements 320 deviate 1-40 degrees from vertical, preferably 5-30 degrees. However, the optimal inclination is dependent on the reaction chamber 110 dimensions and the bottom 130 shape. Advantageously, temperature control of the reaction chamber bottom may be improved as distance between the tapered bottom 130 and heating elements 320 is not allowed to be too large. Cold spots at reaction chamber bottom may be minimized. Consequently, reaction efficiency may be improved and undesired reaction chamber contamination reduced.

In certain embodiments, the top end of vertical heating elements 310 and the top ends of the inclined heating elements 320 are located equally far from the vertical central axis of the reaction chamber 110. In certain embodiments, the top ends of vertical heating elements 310 and the top ends of the inclined heating elements 320 are located equally far from the side wall 160 of the reaction chamber 110 adjacent to which each heating element 310, 320 is located. Advantageously, uniform heating may be provided to top part of the reaction chamber where the reaction chamber is not tapering.

Advantageously, temperature control and heating of the inwards curved or inclined bottom 130 may be improved by the inclined heating elements. Further, temperature control and heating of the reaction chamber bottom 130 close to the exhaust outlet 150 may be improved. Accordingly, more targeted heating of the bottom 130 of the reaction chamber 110 may be provided, and magnitude of temperatures gradients at the bottom of the reaction chamber reduced. Moreover, bent elements 340 provide further improved targeted temperature control of the reaction chamber 110 and the bottom 130.

In certain embodiments, at least one of the inclined heating elements 320 comprise a bent section (or bent element) 340. A substrate processing apparatus 110, wherein the heating system comprises bent sections 340 is shown in FIG. 2. In certain embodiments, the bent section 340 comprises a bend (or kink) or a curved shape. In certain embodiments, the bent section 340 is configured to at least partially define the inclination angle of the inclined heating element 320. In certain embodiments, the bent section 340 is configured to bring the lower end of the inclined heating element 320 further closer to the bottom 130. In certain embodiments, the bent section 340 comprises gradual curvature of the inclined heating element 320 (towards the reaction chamber 110) to further bring the lower end of the inclined heating element 320 closer to the bottom 130. Advantageously, further improved targeted temperature control of the reaction chamber 110 and the bottom 130 may be provided. Consequently, temperature gradients within the reaction chamber 110 may be minimized.

In certain embodiments, the vertical and inclined heating elements 310, 320 are shaped as a rod, tube, beam, wire, or plate. In certain embodiments, the vertical and inclined heating elements 310, 320 are shaped as a linear rod, tube, beam, wire, or plate.

In certain embodiments, the heating system comprises a mixture of vertical and inclined heating elements 310, 320. In certain embodiments, the heating system comprises vertical heating elements 310 and inclined heating elements 320, wherein the alignment of the vertical heating elements 310 is different from the alignment of the inclined heating elements 320 with respect to vertical dimension V. In certain embodiments, the vertical heating elements 310 are parallel to the vertical dimension V. In certain embodiments, the inclined heating elements 320 deviate from the vertical dimension V.

In certain embodiments, the heating system comprises one or more lateral heating elements 330. In certain embodiments, the lateral heating elements 330 are arranged to connect adjacent vertical 310 and/or inclined 320 heating elements to each other. In certain embodiments, the lateral heating elements 330 are straight. In certain embodiments, the lateral heating elements 330 are curved. Advantageously, heating dimensions and heating efficacy of the heating system may be improved.

In certain embodiments, the vertical 310, inclined 320 and lateral heating elements 330 are connected to each other so as to form one continuous heating element around the reaction chamber 110. In certain embodiments, the continuous heating element has a (vertically) meandering shape. Advantageously, the heating system controls and connections may be simplified as the heating elements 310, 320, 330 form a single unified heating element to be operated and regulated.

In certain embodiments, the vertical, inclined or lateral heating elements 310, 320, 330 are shaped as a rods, tubes, beams, wires, or plates. Advantageously, heating elements with different shapes and sizes may be used to optimize the heating system according to the dimensions of the reaction chamber 110.

In certain embodiments, the heating elements 310, 320, 330 are not in direct contact with the reaction chamber 110. Advantageously, steep temperature gradients and sudden temperature differences due to direct contact may be avoided. Accordingly, more uniform temperature control and heating of the reaction chamber 110 may be achieved.

In certain embodiments, when the reaction chamber 110 is arranged to accommodate a horizontal stack of vertically aligned substrates 120, the heating system is configured to surround the reaction chamber along a horizontal plane which is parallel to the horizontally aligned height axis of the stack of substrates 120 so that both ends of the stack of substrates 120 are aligned towards a section of the heating system comprising vertical heating elements 310. In certain embodiments, ends of the horizontal stack of substrates 12 are aligned towards one or more vertical heating elements 310. In certain embodiments, height axis of the horizontal stack of substrates 120 is aligned perpendicularly towards one or more vertical heating elements 310. That is, the height axis of the stack of substrates 120 is points towards vertical heating elements 310. Consequently, the heating system may effectively heat also the ends of the stack of substrates 120. Advantageously, also the ends of the stack of substrates 120 are surrounded by the heating system and may be effectively heated (and not only the sides of the stack of substrates). Accordingly, temperature differences between the ends and middle part of the stack of substrates 120 may be minimized. Consequently, the stack of substrates 120 may be more uniformly heated.

In certain embodiments, the heating system is arranged to heat the ends of a stack of substrates 120 arranged within the reaction chamber 110 for processing. In certain embodiments, the heating system is arranged to heat the ends of a stack of substrates 120 arranged horizontally within the reaction chamber 110. Advantageously, heating of the distal substrates 120 of the stack may be improved.

In certain embodiments, the substrate processing apparatus 100 comprises an outer chamber 210 at least partially surrounding the reaction chamber 110. A space (volume) between the inside of the outer chamber 210 and the outside of the reaction chamber 110 is defined as intermediate space 215. In certain embodiments, the heating system is located within the outer chamber 210 in the intermediate space 215. Advantageously, the heating system may be better protected from external disturbances and, thus, more accurately controlled. Accordingly, temperature control of the reaction chamber 110 may be improved.

In certain embodiments, the heating elements 310, 320, 330 enter the intermediate space through bottom or side walls 160 of the outer chamber 210. Advantageously, connection and control means to control the heating system may be accommodated outside the outer chamber 210. Consequently, maintenance and control of the heating system may be facilitated.

In certain embodiments, the pressure and/or gas compositions within the intermediate space 215 is controlled during substrate processing.

In certain embodiments, the outer chamber 210 comprises an openable and closable top part 230, such as a lid. The lid enables loading and unloading of the stack of substrates 120 to and form the reaction chamber 110 located within the outer chamber 210 through the top.

In certain embodiments, the exhaust outlet 150 extends from the bottom of the reaction chamber 111 through the bottom of the outer chamber 210. In certain embodiments, the exhaust outlet 150 is connected to the exhaust line 155 outside the outer chamber 210.

In certain embodiments, the substrate processing apparatus 100 comprises a heating collar 400 arranged to heat the exhaust outlet 150. In certain embodiments, the heating collar comprises resistive heating elements. An exemplary heating collar 400 is depicted in FIG. 4.

In certain embodiments, the heating collar 400 is attachable around the exhaust outlet 150 outside the reaction chamber 110. In certain embodiments, the heating collar 400 is attachable around the exhaust outlet 150 outside the outer chamber 210. In certain embodiments, the heating collar 400 is attached around the point where the exhaust outlet 150 is connected to the exhaust line 155. Advantageously, cold spot formation and steep temperature gradient at the exhaust outlet 150 may be further minimized.

In certain embodiments, the heating collar comprises a first part 410 and a second part 420. In certain embodiments, the first part 410 and second part are detachable from each other to enable attachment and removal of the heating collar 400 around the exhaust outlet 150. In certain embodiments, the heating collar comprises connection means 430 to attach connectors and cables to the heating collar 400 to operate the heating collar 400.

Without limiting the scope and/or interpretation of the claims, certain technical effects and/or advantages of one or more of the example embodiments disclosed herein are listed in the following. An advantage is improved temperature control of substrate processing apparatus. Particularly, temperature non-uniformity within the reaction chamber, within a substrate and between substrates of a batch of substrates may be reduced. Another advantage is that processing conditions, processing quality and reaction efficiency may be improved. Further advantage is that heating efficacy may be improved and heating time reduced. Further, direction and transmission of heat energy may be better controlled and targeted. Yet another advantage is improved thin film growth rate. The one or more advantages may be realized due to improved temperature control and more stable and uniform processing conditions.

Various embodiments have been presented. It should be appreciated that in this document, words comprise, include, and contain are each used as open-ended expressions with no intended exclusivity.

The foregoing description has provided by way of non-limiting examples of particular implementations and embodiments a full and informative description of the best mode presently contemplated by the inventors for carrying out the invention. It is however clear to a person skilled in the art that the invention is not restricted to details of the embodiments presented in the foregoing, but that it can be implemented in other embodiments using equivalent means or in different combinations of embodiments without deviating from the characteristics of the invention.

Furthermore, some of the features of the afore-disclosed example embodiments may be used to advantage without the corresponding use of other features. As such, the foregoing description shall be considered as merely illustrative of the principles of the present invention, and not in limitation thereof. Hence, the scope of the invention is only restricted by the appended patent claims.

1. A substrate processing apparatus comprising:
a reaction chamber defining a processing volume for processing a stack of substrates, wherein the reaction chamber comprises a downwards tapering bottom, wherein the bottom is arranged to taper towards an exhaust outlet; and
a heating system outside the processing volume, wherein the heating system comprises inclined heating elements, wherein the inclined heating elements are inclined from vertical so that lower ends of the inclined heating elements are arranged inwards towards the exhaust outlet to heat the tapering reaction chamber bottom.

2. The substrate processing apparatus of claim 1, wherein the tapering of the bottom comprises narrowing down horizontal cross section of the reaction chamber only along one horizontal dimension, a first horizontal dimension, when approaching the exhaust outlet.

3. The substrate processing apparatus of claim 1, wherein the inclined heating elements are arranged symmetrically at opposite sides of the processing volume.

4. The substrate processing apparatus of claim 1, wherein the heating system further comprises vertical heating elements arranged outside the processing volume parallel to vertical side walls of the reaction chamber.

5. The substrate processing apparatus of claim 1, wherein the heating system comprises lateral heating elements configured to connect adjacent inclined heating elements and/or vertical heating elements to each other.

6. The substrate processing apparatus of claim 5, wherein the inclined heating elements, vertical heating elements and lateral heating elements are connected to each other to form a continuous heating element around the processing volume.

7. The substrate processing apparatus of claim 1, wherein the inclined heating elements comprise at least one bent section to at least partially define the inclination angle of the inclined heating elements.

8. The substrate processing apparatus of claim 1, comprising an outer chamber at least partially surrounding the reaction chamber, wherein the heating elements of the heating system are located outside the reaction chamber within the outer chamber.

9. The substrate processing apparatus of claim 1, wherein the heating elements of the heating system are embedded within the side walls and the bottom of the reaction chamber.

10. The substrate processing apparatus of claim 1, configured to accommodate the stack of substrates within the processing volume as a horizontal stack of vertically aligned substrates.

11. The substrate processing apparatus of claim 10, wherein the inclined heating elements are transversely located in relation to the height direction of the stack of substrates on opposite sides of the stack.

12. The substrate processing apparatus of claim 10, wherein each end of the horizontal stack of substrates is aligned towards one or more vertical heating elements.

13. The substrate processing apparatus of claim 10, wherein the bottom is configured to conform to the shape of the horizontal stack of substrates.

14. The substrate processing apparatus of claim 1, wherein the reaction chamber has rectangular horizontal cross section.

15. The substrate processing apparatus of claim 1, comprising a heating collar arranged to heat the exhaust outlet.

16. The substrate processing apparatus of claim 1, wherein height of the heating system is at least 90% of height of the reaction chamber.

17. The substrate processing apparatus of claim 2, wherein the inclined heating elements are arranged symmetrically at opposite sides of the processing volume.

18. The substrate processing apparatus of claim 2, wherein the heating system further comprises vertical heating elements arranged outside the processing volume parallel to vertical side walls of the reaction chamber.

19. The substrate processing apparatus of claim 3, wherein the heating system further comprises vertical heating elements arranged outside the processing volume parallel to vertical side walls of the reaction chamber.

20. The substrate processing apparatus of claim 2, wherein the heating system comprises lateral heating elements configured to connect adjacent inclined heating elements and/or vertical heating elements to each other.
